(19) United States
(12) Patent Application Publication
(10) Pub. No.: US 2008/0224180 A1
(43) Pub. Date: Sep. 18, 2008

(54) RADIATION DETECTING SYSTEM

(75) Inventor: Fumito NARIYUKI, Ashigarakami-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/048,557

(22) Filed: Mar. 14, 2008

(30) Foreign Application Priority Data
Mar. 15, 2007 (JP) 2007-066406

(51) Int. Cl. H01L 31/032

(52) U.S. Cl. 257/226; 257/E31.029

(57) ABSTRACT

A radiation detecting system includes at least a carrier collective electrode layer, a radiation-sensitive semiconductor layer, at least one charge transfer layer, and a voltage applying electrode formed on an insulating substrate and wherein at least one of the charge transfer layers includes chalcogenide compounds containing therein chalcogenide elements larger than the stoichiometric value by not smaller than 3% of the stoichiometric value in a composition thereof.

### BACKGROUND OF THE INVENTION

1. Field of the Invention

This invention relates to a radiation detecting system suitable for applying to a radiation image taking system such as an X-ray system.

2. Description of the Related Art

There has been in wide use in the medical or industrial field, a radiation detecting system using an image recording medium (radiation sensor) which stores electric charges generated in response to projection of radiation such as X-rays or γ-rays as latent image charges.

For example, in the X-ray imaging for a medical use, there has been known a radiation detecting system as disclosed in, for instance, U.S. Pat. No. 4,535,468 where a image recording medium having a photosensitive body represented by selenium sensitive to radiation such as x-rays is used as a photosensitive body and radiation amount information converted to electric charges is detected by an optical read-out system using a scanning laser or linear light. Further, there has been known a radiation detecting system as disclosed in, for instance, U.S. Pat. Nos. 6,495,817 and 6,642,534, where selenium is used as a photosensitive body and radiation amount information converted to electric charges is detected by an electrical read-out system using a TFT (thin film transistor). By the use of such an image recording medium, for example, the dose of radiation to which the examinee is exposed can be reduced and at the same time, the diagnostic performance can be improved.

In direct conversion type X-ray systems, there is often used a-Se (amorphous selenium) as a radiation-sensitive semiconductor layer in that it exhibits a high dark resistance and excellent in response. Further it has been proposed to form a carrier-selective semi-insulating or dielectric layer (charge transfer layer) on one side or both sides of the photoconductive layer (radiation-sensitive semiconductor layer), which may be formed of, for instance, Sb₂S₃ (U.S. Pat. Nos. 6,495,817 and 6,642,534, and the like).

However, in the radiation detecting systems where the Sb₂S₃ layer is used between the radiation-sensitive semiconductor layer and the substrate, there is apt to generate a peeling off under low temperatures or high temperatures, and in the radiation detecting systems where the Sb₂S₃ layer is used between the radiation-sensitive semiconductor layer and the voltage-applying electrode, there sometimes occurs a deterioration with aging, or generation of crack under low temperatures or high temperatures.

### SUMMARY OF THE INVENTION

In view of the foregoing observations and description, the primary object of the present invention is to provide a radiation detecting system which is free from the peeling off or the crack of the charge transfer layer by controlling the composition of the charge transfer layer including chalcogenide compounds the representative of which is Sb₂S₃.

In accordance with a first form, the present invention provides a radiation detecting system including at least a carrier collective electrode layer, a radiation-sensitive semiconductor layer, at least one charge transfer layer, and a voltage applying electrode formed on an insulating substrate and characterized in that at least one of the charge transfer layers includes chalcogenide compounds containing therein chalcogenide elements larger than the stoichiometric value by not smaller than 3% of the stoichiometric value in a composition thereof.

In accordance with a second form, the present invention provides a radiation detecting system including at least a carrier collective electrode layer, a radiation-sensitive semiconductor layer, at least one charge transfer layer, and a voltage applying electrode formed on an insulating substrate and characterized in that at least one of the charge transfer layers includes chalcogenide compounds containing therein chalcogenide elements larger than the stoichiometric value by not smaller than 3% of the stoichiometric value in the vicinity of one of the interfaces of the charge transfer layer in a composition thereof.

The “vicinity of the interfaces” as used here means an area apart from the interface between adjacent layer by a thickness not larger than 10 nm the interface inclusive.

In accordance with a third form, the present invention provides a radiation detecting system including at least a carrier collective electrode layer, a radiation-sensitive semiconductor layer, at least one charge transfer layer, and a voltage applying electrode formed on an insulating substrate and characterized in that at least one of the charge transfer layers includes chalcogenide compounds containing therein chalcogenide elements which gradually approach the stoichiometric value from the value larger than the stoichiometric value by not smaller than 3% of the stoichiometric value in a composition thereof from the interfaces toward the center.

It is more preferred that the chalcogenide compound be antimony sulfide. It is preferred that the radiation-sensitive semiconductor layer be a layer of Na-doped a-Se.

When the radiation detecting system of the present invention comprises the carrier collective electrode layer, the radiation-sensitive semiconductor layer, the charge transfer layer, and the voltage applying electrode formed in this order on the insulating substrate, it is more preferred that a-Se layer containing at least one of As, Sb and Bi in 0.1 wt % to 10 wt % be provided between the radiation-sensitive semiconductor layer and the charge transfer layer.

When the radiation detecting system of the present invention comprises the carrier collective electrode layer, the charge transfer layer, the radiation-sensitive semiconductor layer, and the voltage applying electrode formed in this order on the insulating substrate, it is more preferred that a-Se layer (to be referred to as “intermediate layer”, hereinbelow) containing at least one of As, Sb and Bi in 0.1 wt % to 10 wt % be provided between the radiation-sensitive semiconductor layer and the charge transfer layer.

Since the first to third radiation detecting systems of the present invention include, in their charge-transfer layer, chalcogenide compounds containing therein chalcogenide elements larger than the stoichiometric value by not smaller than 3% of the stoichiometric value in a composition thereof, generation of the crack in the charge-transfer layer can be suppressed whereby image defect which has been believed due to crack can be suppressed and at the same time, the charge-transfer layer can be suppressed from peeling off.

Especially when the radiation-sensitive semiconductor layer comprises a-Se, the radiation-sensitive semiconductor layer becomes apt to crystallize when the temperature is beyond 48° C. since the a-Se is 48° C. in transition point temperature Tg (Tg=48° C.) and very apt to crystallize. Further, the radiation-sensitive semiconductor layer is apt to crystallize depending on the material or the morphology thereof in contact with the a-Se layer. Since the crystallization involves problems especially on interfaces, the cracks generated in the charge transfer layers introduces crystallization of the a-Se layer and generates an image defect. Since the radiation detecting system of the present invention includes, in its charge-transfer layer, chalcogenide compounds containing therein chalcogenide elements larger than the stoichiometric value by not smaller than 3% of the stoichiometric value in a composition thereof, generation of crystallization in the radiation-sensitive semiconductor layer is greatly suppressed, whereby generation of image defect can be greatly suppressed.

When the radiation detecting system of the present invention comprises the carrier collective electrode layer, the radiation-sensitive semiconductor layer, the charge transfer layer, and the voltage applying electrode formed in this order on the insulating substrate, or the carrier collective electrode layer, the charge transfer layer, the radiation-sensitive semiconductor layer, and the voltage applying electrode formed in this order on the insulating substrate, by providing an intermediate layer between the radiation-sensitive semiconductor layer and the charge transfer layer, generation of the crack in the charge-transfer layer can be more suppressed and the charge-transfer layer can be more suppressed from peeling off.

Especially when the radiation-sensitive semiconductor layer comprises a-Se, though the radiation-sensitive semiconductor layer becomes apt to crystallize when the temperature goes beyond the transition point temperature Tg as described above, generation of the crystallization in the charge-transfer layer can be greatly reduced whereby generation of image defect can be greatly suppressed by providing an intermediate layer between the radiation-sensitive semiconductor layer and the charge transfer layer.

### BRIEF DESCRIPTION OF THE DRAWINGS

FIG. 1 is a schematic cross-sectional view showing the radiation taking system in accordance with an embodiment of the present invention,

FIG. 2 is a schematic cross-sectional view showing the radiation taking system in accordance with another embodiment of the present invention,

FIG. 3 is a schematic cross-sectional view showing the radiation taking system in accordance with still another embodiment of the present invention,

FIG. 4 is a schematic cross-sectional view showing the radiation taking system with an intermediate layer in accordance with the present invention,

FIG. 5 is a schematic cross-sectional view showing the radiation taking system with the intermediate layer in accordance with another embodiment of the present invention.

### DESCRIPTION OF THE PREFERRED EMBODIMENT

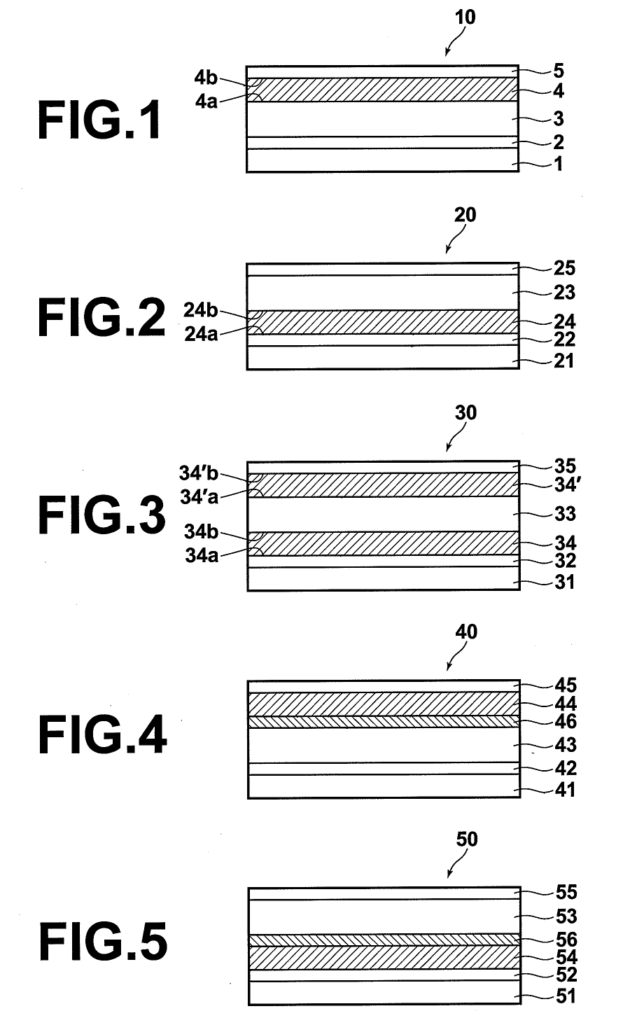

Embodiments of radiation detecting system of the present invention will be described with reference to the drawings, hereinbelow. FIG. 1 is a schematic cross-sectional view showing the radiation taking system in accordance with an embodiment of the present invention, FIG. 2 is a schematic cross-sectional view showing the radiation taking system in accordance with another embodiment of the present invention, and FIG. 3 is a schematic cross-sectional view showing the radiation taking system in accordance with still another embodiment of the present invention.

The radiation taking system 10 shown in FIG. 1 comprises a carrier collective electrode layer 2, a radiation-sensitive semiconductor layer 3, a charge transfer layer 4, and a voltage applying electrode layer 5 formed in sequence on an insulating substrate 1. The radiation taking system 20 shown in FIG. 2 comprises a carrier collective electrode layer 22, a charge transfer layer 24, a radiation-sensitive semiconductor layer 23, and a voltage applying electrode layer 25 formed in sequence on an insulating substrate 21. The radiation taking system 30 shown in FIG. 3 comprises a carrier collective electrode layer 32, a first charge transfer layer 34, a radiation-sensitive semiconductor layer 33, a second charge transfer layer 34′, and a voltage applying electrode layer 35 formed in sequence on an insulating substrate 31. FIGS. 1 and 2 show radiation taking systems having one charge transfer layer and FIG. 3 show a radiation taking system having a pair of charge transfer layers.

In the radiation detecting system of the present invention, the carrier collective electrode layer 22 and the voltage applying electrode layer 25 are applied with a high voltage to generate a high voltage electric field in the radiation-sensitive semiconductor layer 33 therebetween, and separates electron-positive-hole pairs generated by the radiation energy projected thereonto thereby generating signal carriers. As the signal read-out mechanism, those using an optical read-out system where reading light (reading electromagnetic waves) is projected onto a sensor or a TFT read-out system where TFTs (thin film transistor) connected to the electric charge storing portion are driven can be used.

It is preferred that the charge transfer layer of the radiation detecting system in accordance with the present invention reads out the electric charges (carriers) generated in the radiation-sensitive semiconductor layer to the carrier collective electrode layer and the voltage applying electrode layer and at the same time, prevents injection of the carrier into the radiation-sensitive semiconductor layer to suppress a leak current. The charge transfer layer may be provided in a plurality and the charge transfer layers may be provided between the radiation-sensitive semiconductor layer and the voltage applying electrode layer as shown in FIG. 1 or between the radiation-sensitive semiconductor layer and the carrier collective electrode layer as shown in FIG. 2, or both of between the radiation-sensitive semiconductor layer and the voltage applying electrode layer and between the radiation-sensitive semiconductor layer and the carrier collective electrode layer as shown in FIG. 3. The charge transfer layer may either be in a direct contact with the radiation-sensitive semiconductor layer, the carrier collective electrode layer or the voltage applying electrode layer, or in contact with these layers intervening therebetween other layers.

The charge transfer layer of the present invention wholly includes chalcogenide compounds containing therein chalcogenide elements larger than the stoichiometric value not smaller than 3% of the stoichiometric value in a composition thereof (sometimes referred to as “non-stoichiometric value”) as in the radiation detecting systems of the following first and second forms of the present invention.

That is, in the radiation detecting system in accordance with a first form of the present invention shown in FIG. 1 or 2 where one charge transfer layer is provided, the charge transfer layer includes chalcogenide compounds containing therein chalcogenide elements larger than the stoichiometric value by not smaller than 3% of the stoichiometric value in a composition thereof and in the radiation detecting system in accordance with a first form of the present invention shown in FIG. 3 where a pair of charge transfer layers are provided, at least one of the charge transfer layers 34 and 34′ includes chalcogenide compounds containing therein chalcogenide elements larger than the stoichiometric value by not smaller than 3% of the stoichiometric value in a composition thereof. It is preferred that in accordance with a first form of the present invention shown in FIG. 3 where a pair of charge transfer layers are provided, the charge transfer layers 34 and 34′ both include chalcogenide compounds containing therein chalcogenide elements larger than the stoichiometric value by not smaller than 3% of the stoichiometric value in a composition thereof.

The charge transfer layer of the present invention need not wholly include chalcogenide compounds containing therein chalcogenide elements in non-stoichiometric value but may partly include chalcogenide compounds containing therein chalcogenide elements in non-stoichiometric value as in the radiation detecting systems of the following second and third forms of the present invention.

Specifically, in the radiation detecting system of the second form of the present invention shown in FIG. 1 where one charge transfer layer is provided, the charge transfer layer includes chalcogenide compounds containing therein chalcogenide elements larger than the stoichiometric value by not smaller than 3% of the stoichiometric value in a composition thereof in the vicinity of one of the interface 4a of the charge transfer layer 4 with the radiation-sensitive semiconductor layer 3 and the interface 4b of the charge transfer layer 4 with the voltage applying electrode layer 25. In the radiation detecting system of the second form of the present invention shown in FIG. 2 where one charge transfer layer is provided, the charge transfer layer 24 includes chalcogenide compounds containing therein chalcogenide elements larger than the stoichiometric value by not smaller than 3% of the stoichiometric value in a composition thereof in the vicinity of one of the interface 24a of the charge transfer layer 4 with the carrier collective layer 22 and the interface 24b of the charge transfer layer 24 with the radiation-sensitive semiconductor layer 23. In the radiation detecting system of the present invention shown in FIG. 3 where a pair of charge transfer layers are provided, at least one of the charge transfer layers 34 includes chalcogenide compounds containing therein chalcogenide elements larger than the stoichiometric value by not smaller than 3% of the stoichiometric value in a composition thereof in the vicinity of either one of the interface 34a of the charge transfer layer 34 with the carrier collective layer 32 and the interface 34b of the charge transfer layer 34 with the radiation-sensitive semiconductor layer 33 or one of the interface 34′a of the charge transfer layer 34 with the radiation-sensitive semiconductor layer 33 and the interface 34′b of the charge transfer layer 34 with the voltage applying electrode layer 35.

It is further preferred that in the radiation detecting system of the second form of the present invention, at least one of the charge transfer layers includes chalcogenide compounds containing therein chalcogenide elements larger than the stoichiometric value by not smaller than 5% of the stoichiometric value in a composition thereof. It is further preferred that in the radiation detecting system shown in FIG. 1, the charge transfer layers include chalcogenide compounds containing therein chalcogenide elements larger than the stoichiometric value by not smaller than 5% of the stoichiometric value in a composition thereof both in the vicinity of the interface 4a of the charge transfer layer 4 with the radiation-sensitive semiconductor layer 3 and the interface 4b of the charge transfer layer 4 with the voltage applying electrode layer 25. In the radiation detecting system shown in FIG. 2, at least one of the charge transfer layers 24 includes chalcogenide compounds containing therein chalcogenide elements larger than the stoichiometric value by not smaller than 5% of the stoichiometric value in a composition thereof both in the vicinity of the interface 24a of the charge transfer layer 4 with the carrier collective layer 22 and the interface 24b of the charge transfer layer 24 with the radiation-sensitive semiconductor layer 23. In the radiation detecting system shown in FIG. 3 where a pair of charge transfer layers are provided, the charge transfer layers 34 include chalcogenide compounds containing therein chalcogenide elements larger than the stoichiometric value by not smaller than 5% of the stoichiometric value in a composition thereof both in the vicinity of either one of the interface 34a of the charge transfer layer 34 with the carrier collective layer 32 and the interface 34b of the charge transfer layer 34 with the radiation-sensitive semiconductor layer 33 or one of the interface 34′a of the charge transfer layer 34 with the radiation-sensitive semiconductor layer 33 and the interface 34′b of the charge transfer layer 34 with the voltage applying electrode layer 35.

The thickness of the charge transfer layer is preferably not larger than 10 nm and not smaller than 50 μm, more preferably not larger than 30 nm and not smaller than 10 μm, and most preferably not larger than 50 nm and not smaller than 5 μm. The “vicinity of the interfaces” as used here means an area apart from the interface by a thickness preferably not smaller than 10 nm and more preferably not smaller than 50 nm.

In the radiation detecting systems of the third form of the present invention shown in FIGS. 1 and 2 where one charge transfer layer is provided, the composition of the chalcogenide compounds included in the charge transfer layer contains therein chalcogenide elements which gradually approach the stoichiometric value from the value larger than the stoichiometric value by not smaller than 3% of the stoichiometric value from the interfaces toward the center. In the radiation detecting system of the third form of the present invention shown in FIG. 1, the composition of the chalcogenide compounds included in the charge transfer layer contains therein chalcogenide elements which gradually approach the stoichiometric value from the value larger than the stoichiometric value by not smaller than 3% of the stoichiometric value from the interface 4a or the interface 4b toward the center. In the radiation detecting system of the third form of the present invention shown in FIG. 2, the composition of the chalcogenide compounds included in the charge transfer layer contains therein chalcogenide elements which gradually approach the stoichiometric value from the value larger than the stoichiometric value by not smaller than 3% of the stoichiometric value from the interface 24a or the interface 24b toward the center. In the radiation detecting system of the present invention shown in FIG. 3 where a pair of charge transfer layers are provided, the composition of the chalcogenide compounds included in one or both of the charge transfer layer from the interface 24a or the interface 24b toward the center.

The chalcogenide compound in the present invention includes antimony sulfide (Sb₂S₃), zinc sulfide (ZnS), As₂S₃, CdS, CdZnTe and the like. As₂S₃ and Sb₂S₃ are preferably used with a-Se from the viewpoint of transferability of the generated electric charges. Sb₂S₃ is more preferably used with a-Se.

That the chalcogenide compound in the present invention contains therein chalcogenide elements which is larger than the stoichiometric value by not smaller than 3% of the stoichiometric value as used here means that, for instance, in a stoichiometric composition Sb₂S₃(Sb₄₀S₆₀), the chalcogenide compound in the present invention has a composition of Sb₍₁₀₀₋ₓ₎Sₓ (x≧61.8 (=60×1.03)). When the chalcogenide compound in the present invention contains therein a plurality of chalcogenide elements, the contents of the plurality of chalcogenide elements are larger than the stoichiometric value by not smaller than 3% of the stoichiometric value. In order to realize a non-stoichiometric composition, elements other than the component elements of the stoichiometric composition may be included. However, in this case, the elements are divided into chalcogenide elements and non-chalcogenide elements, and deviation from the stoichiometric composition is determined by whether the element is chalcogenide elements or non-chalcogenide elements.

As a non-stoichiometric composition with respect to the stoichiometric composition Sb₂S₃, composition of Sb₍₁₀₀₋ₓ₎Sₓ (63≦x≦80) is preferred and composition of Sb₍₁₀₀₋ₓ₎Sₓ (68≦x≦80) is more preferred. It is conceivable that the reason why the contents of chalcogenide elements should deviate toward plus from the stoichiometric composition is that since increase of the chalcogenide elements increases the thermal expansion coefficient, crack due to change in temperature is less apt to be generated when laminated on material larger than Sb₂S₃ in the thermal expansion coefficient. Further, it is conceivable that increase of the chalcogenide elements improves close contact with adjacent layers.

When production of the chalcogenide compound the chalcogenide element contents of which are larger than the stoichiometric value by not smaller than 3% of the stoichiometric value is described on Sb₂S₃ by way of example, the procedure is as follows. First, raw material of the antimony sulfide to be deposited is prepared. That is, sulfur as simple substance and antimony as simple substance are measured in amounts corresponding to a ratio in a desired composition and they are put into a glass vessel and sealed under a vacuum. Then homogeneous molten antimony sulfide is obtained by heating the glass vessel to not lower than melting point of the antimony (630° C.) while vibration-stirring the mixture for not shorter than 15 hours. Thereafter, chunk-like antimony sulfide is taken out from the glass vessel after natural cooling. The chunk-like antimony sulfide taken out is loaded in the depositing port in the form of powders or pellets, and an antimony sulfide layer having a desired composition ratio is produced by depositing them.

The composition of the charge transfer layer can be measured by, for instance, one of methods of (1) cutting out a cross-section of the radiation detecting system, and mapping the composition of a part corresponding to the charge transfer layer with an energy-dispersion type X-ray analysis system (EDX) (2) scraping out a part corresponding to the charge transfer layer and measuring an average composition by fluororoentogenology (XRF method) and (3) peeling off the radiation detecting system in the direction of layers in the vicinity of the charge transfer layer, and measuring by thin film XRF method.

As the radiation-sensitive semiconductor layer in the radiation detecting system of the present invention, a-Se, HgI₂, PbI₂, CdS, CdSe, CdTe, BiI₃ and the like can be used. Especially when the radiation-sensitive semiconductor layer comprises a Na-modified a-Se layer, generation of crystallization in the radiation-sensitive semiconductor layer is greatly reduced, whereby generation of image defect can be greatly suppressed if charge transfer layer includes a chalcogenide compound of the present invention.

In the radiation detecting system 40 where a carrier collective electrode layer 42, a radiation-sensitive semiconductor layer 43, a charge transfer layer 44 and a voltage applying electrode layer 45 are formed in this order on an insulating substrate 41, the radiation detecting system of the present invention may be provided with Se layer (an intermediate layer) 46 containing at least one of As, Sb and Bi in 0.1 wt % to 10 wt % between the radiation-sensitive semiconductor layer 43 and the charge transfer layer 44 as shown in FIG. 4. Otherwise, in the radiation detecting system 50 where a carrier collective electrode layer 52, a charge transfer layer 54, a radiation-sensitive semiconductor layer 53, and a voltage applying electrode layer 55 are formed in this order on an insulating substrate 51, the radiation detecting system of the present invention may be provided with a similar intermediate layer 56 between the radiation-sensitive semiconductor layer 53 and the charge transfer layer 54 as shown in FIG. 5. By thus providing an intermediate layer, generation of crack in the charge transfer layer can be suppressed.

When at least one of As, Sb and Bi contained in Se is smaller than 0.1 wt %, the effect of suppressing generation of crack in the charge transfer layer cannot be obtained, and when at least one of As, Sb and Bi contained in Se is larger than 10 wt %, the lag (the attenuation of the afterimage after the radiation signals are cut) deteriorates. When elements selected from the group formed of As, Sb and Bi contained in Se are in a plurality, the contents mean the sum of the wt's of the respective elements.

As the carrier collective electrode layer used in the radiation detecting system of the present invention, any material may be used so long as it is conductive. However, the carrier collective electrode layer preferably transmits visible light, and for instance, ITO (indium/tin oxide), and IZO (indium/zinc oxide) can be used. As the voltage applying electrode layer used in the radiation detecting system of the present invention, any material may be used so long as it is conductive. For instance, Au, Al and the like can be used. Since the charge transfer layer in the radiation detecting system of the present invention can be brought into a good contact with Au, peeling off of the charge transfer layer from the voltage applying electrode layer can be more suppressed.

The radiation detecting system of the present invention will be described in more detail with reference to embodiments, hereinbelow.

### Embodiment 1

a-Se radiation-sensitive semiconductor layer was formed in thickness of 1000 μm on a substrate on which switching TFT's were arranged. Thereafter, a boat in which antimony sulfide which was Sb₂₀S₈₀ in average composition was placed was heated to 555° C. to form a charge transfer layer in thickness of 1 μm. Finally, a voltage applying electrode layer was formed in 50 nm by heating Au by resistance-heating, thereby obtaining a radiation detecting system.

### Embodiment 2

A radiation detecting system was produced in the same manner as the embodiment 1 except that antimony sulfide which was Sb₃₃S₆₇ in average composition was used as the row material in place of antimony sulfide which was Sb₂₀S₈₀ in average composition.

### Embodiment 3

A radiation detecting system was produced in the same manner as the embodiment 1 except that antimony sulfide which was Sb₃₂S₆₈ in average composition was used as the row material in place of antimony sulfide which was Sb₂₀S₈₀ in average composition.

### COMPARATIVE EXAMPLE 1

A radiation detecting system was produced in the same manner as the embodiment 1 except that antimony sulfide which was Sb₂S₃ in composition was used as the row material in place of antimony sulfide which was Sb₂₀S₈₀ in average composition.

### (Evaluation)

The dark-current was measured on the basis of the test pattern on the substrate. The measurement was executed with the voltage applying electrode layer applied with a voltage of +10 kV and the carrier collective electrode grounded.

Afterimage was evaluated by projecting 300 mR X-ray pulses at the tube voltage of 80 kV and on the basis of the common logarithm log(IA/IL) of the ratio of the light current IA during projection of the pulses to the leak current IL 15 seconds after termination of the pulses. As this value becomes larger, attenuation of the signals after the X-ray projection is cut is earlier, that is, the afterimage is less. In this evaluation, the value of lag is preferably is not less than 3.0 and more preferably is not less than 3.2.

Crystallization of a-Se was evaluated through a measurement of the microscopic Raman spectrum. It was confirmed on the basis of the phenomenon that the band (256 cm⁻¹) reverting to expansion and contraction vibration of Se-Se was shifted to 237 cm⁻¹ by crystallization. Specifically, a part of a-Se including the organic-polymer side interface was embedded in epoxy resin to be surrounded thereby, and was cut with a diamond microtome to expose an interface of a-Se. Arbitrary 50 points were extracted horizontally from the area apart from the interface of a-Se by 1 μm in the direction of the depth and measured, and the proportion of the number of the points where a crystallized a-Se peak was detected was calculated. When the number of the points where an a-Se was crystallized is 0, the evaluation is ⊚ (excellent), when the number was in the range of 0 to 3, the evaluation is ∘ (good), when the number was in the range of 3 to 10, the evaluation is Δ (fair), when the number was not less than 10, the evaluation is × (poor).

The composition of the formed antimony sulfide layer was measured by EDX method by cutting out a cross-section after the above measurement.

The contact between Au and the charge transfer layer was evaluated by conducting grid tape peeling test according to JIS D0202-1988. Cellophane tape (“CT 24”: manufactured by “Nichiban Inc.”) was brought into a close contact with the film with a bulb of a finger and then peeled off the film. Evaluation was represented by the number of grids which were not peeled off. That none of the Au electrode was not peeled off was represented by 20/20 while that the Au electrode was perfectly peeled off was represented by 0/20.

Result was shown in the following table 1.

As shown in table 1, in the embodiments 1 to 3 whose Sb contents are larger than the stoichiometric value by not smaller than 3% of the stoichiometric value, crystallization in interface with a-Se layer is less apt to occur as compared with in the comparative example 1 whose Sb contents are the stoichiometric value. Further, as shown in table 1, the embodiments 1 to 3 are more excellent also in contact of the charge transfer layer with the Au electrode to the comparative example 1.

TABLE 1

| | composition | | | |
|---|---|---|---|---|
| | of the charge | | | |
| | transfer layer | | | |
| | | interface | | peeling off |
| | interface | with Au | crystallization | of Au |
| | with a-Se | electrode | of a-Se layer | electrode |
| embodiment 1 | Sb₂₂S₇₈ | Sb₂₃S₇₇ | ⊚ | 19/20 |
| embodiment 2 | Sb₃₃S₆₇ | Sb₃₄S₆₆ | ⊚ | 19/20 |
| embodiment 3 | Sb₃₈S₆₂ | Sb₃₈S₆₂ | ◯ | 15/20 |
| comparative | Sb₄₀S₆₀ | Sb₄₁S₅₉ | Δ | 10/20 |
| example 1 | | | | |

### Embodiment 4

A radiation detecting system was produced in the same manner as the embodiment 1 except that a charge transfer layer in thickness of 2 μm was formed by the use of antimony sulfide which was Sb₂₀S₈₀ in average composition, then an a-Se radiation-sensitive semiconductor layer in thickness of 1000 μm was formed and finally an Au layer is formed in thickness of 50 nm was formed to form a voltage applying electrode layer on the IZO electrode.

### Embodiment 5

A radiation detecting system was produced in the same manner as the embodiment 4 except that antimony sulfide which was Sb₃₃S₆₇ in average composition was used as the row material in place of antimony sulfide which was Sb₂₀S₈₀ in average composition.

### COMPARATIVE EXAMPLE 2

A radiation detecting system was produced in the same manner as the embodiment 4 except that antimony sulfide which was Sb₂S₃ in composition was used as the row material in place of antimony sulfide which was Sb₂₀S₈₀ in composition.

### (Evaluation)

The produced radiation system was exposed to the cycle of 35° C., 10 hours and 5° C., 10 hours 10 times, and evaluated whether IZO electrode was peeled off the antimony sulfide layer.

The composition of the formed antimony sulfide layer was measured by EDX method by cutting out a cross-section after the above measurement.

Result was shown in the following table 2.

As shown in table 2, in the embodiments 4 and 5 whose Sb contents are larger than the stoichiometric value by not smaller than 3% of the stoichiometric value, peeling off from the IZO electrode layer is less apt to occur as compared with in the comparative example 2 whose Sb contents are the stoichiometric value.

TABLE 2

| | composition | | |
|---|---|---|---|
| | of the charge | | |
| | transfer layer | | |
| | interface | interface | |
| | with IZO | with a-Se | peeling off |
| embodiment 4 | Sb₂₂S₇₈ | Sb₂₄S₇₆ | No |
| embodiment 5 | Sb₃₃S₆₇ | Sb₃₅S₆₅ | No |
| comparative example 2 | Sb₄₀S₆₀ | Sb₄₁S₅₉ | Much |

(The non-stoichiometric composition only in the vicinity of the interface)

### Embodiment 6

A radiation detecting system was produced in the same manner as the embodiment 2 except that an antimony sulfide layer in thickness of 50 nm was formed by the use of antimony sulfide which was Sb₃₃S₆₇ in average composition, and then a charge-transfer layer in thickness of 0.95 μm was formed by the use of antimony sulfide which was Sb₄₀S₆₀ in average composition. When the crystallization of a-Se layer was evaluated in the same manner as the embodiment 2, similar excellent result was obtained. This proves that excellent result can be obtained even when the charge transfer layer has a non-stoichiometric composition only in the vicinity of the interface.

### Embodiment 7

A radiation detecting system was produced in the same manner as the embodiment 5 except that an antimony sulfide layer in thickness of 50 nm was formed by the use of antimony sulfide which was Sb₃₃S₆₇ in average composition, and then a charge-transfer layer in thickness of 1.95 μm was formed by the use of antimony sulfide which was Sb₄₀S₆₀ in average composition. When peeling off from the IZO electrode was evaluated in the same manner as the embodiment 5, similar excellent result was obtained. This proves that excellent result can be obtained even when the charge transfer layer has a non-stoichiometric composition only in the vicinity of the interface.

### (Continuous Change in the Composition)

### Embodiment 8

A radiation detecting system was produced in the same manner as the embodiment 2 except that a charge-transfer layer was formed in thickness of 1 μm by the use of antimony sulfide which was Sb₃₃S₆₇ in average composition by gradually increasing the temperature of tantalum port from 555° C. to 630° C. after the evaporation is started by heating the tantalum port. When the composition of the formed charge transfer layer was measured by EDX method, it continuously had been changed from Sb₃₃S₆₇ at the interface with a-Se to Sb₄₀S₆₀ at the interface with the electrode. When the crystallization of a-Se layer was evaluated in the same manner as the embodiment 2, similar excellent result was obtained. This proves that excellent result can be obtained even when the charge transfer layer includes chalcogenide compounds containing therein chalcogenide elements which gradually approach the stoichiometric value from the value larger than the stoichiometric value by not smaller than 3% of the stoichiometric value in a composition thereof from the interfaces toward the center.

### Embodiment 9

A radiation detecting system was produced in the same manner as the embodiment 5 except that a charge-transfer layer was formed in thickness of 2 μm by the use of antimony sulfide which was Sb₃₃S₆₇ in average composition by gradually increasing the temperature of tantalum port from 555° C. to 630° C. after the evaporation is started by heating the tantalum port. When the composition of the formed charge transfer layer was measured by EDX method, it continuously had been changed from Sb₃₃S₆₇ at the interface with a-Se to Sb₄₁S₅₉ at the interface with the electrode. When peeling off from the substrate was evaluated in the same manner as the embodiment 5, similar excellent result was obtained. This proves that excellent result can be obtained even when the charge transfer layer includes chalcogenide compounds containing therein chalcogenide elements which gradually approach the stoichiometric value from the value larger than the stoichiometric value by not smaller than 3% of the stoichiometric value in a composition thereof from the interfaces toward the center.

(Result When a Na-doped a-Se Layer or an Intermediate Layer is Used)

### COMPARATIVE EXAMPLE 3

A radiation detecting system was produced in the same manner as the comparative example 1 except that Se doped with 10 ppm Na was used as the row material in place of Se and a Na-doped Se film was formed as an a-Se layer.

### Embodiment 10

A radiation detecting system was produced in the same manner as the embodiment 2 except that Se doped with 10 ppm Na was used in place of Se and a Na-doped Se film was formed as an a-Se layer.

### Embodiment 11

A radiation detecting system was produced in the same manner as the embodiment 10 except that a Se layer doped with 10% As was formed between the a-Se layer and the charge transfer layer.

Whether the crystallization of a-Se layer took place was evaluated in the comparative example 3 and the embodiments 10 and 11 in the same manner as the embodiment 1. Result was shown in the following table 3.

TABLE 3

| | | | composition | |
|---|---|---|---|---|
| | | | of charge | |
| | | intermediate | transfer | crystallization |
| | a-Se layer | layer | layer | of a-Se layer |
| comparative | Na-doped Se | non | Sb₄₀S₆₀ | X |
| example 3 | | | | |
| embodiment | Na-doped Se | non | Sb₃₃S₆₇ | ◯ |
| 10 | | | | |
| embodiment | Na-doped Se | Se layer | Sb₃₃S₆₇ | ⊚ |
| 11 | | doped with | | |
| | | 10% As | | |

As shown in table 3, the effect of the charge transfer layer in the present invention to prevent the crystallization of a-Se is especially remarkable when Na-doped Se was used.

Further, by providing Se layer (intermediate layer) containing at least one of As, Sb and Bi in 0.1 wt % to 10 wt % between the a-Se layer and the charge transfer layer, the effect of the charge transfer layer in the present invention to prevent the crystallization of a-Se is further promoted.

### COMPARATIVE EXAMPLE 4

A radiation detecting system was produced in the same manner as the comparative example 2 except that Se doped with 10 ppm Na was used as the row material in place of Se and a Na-doped Se film was formed as an a-Se layer.

### Embodiment 12

A radiation detecting system was produced in the same manner as the embodiment 2 except that Se doped with 10 ppm Na was used in place of Se and a Na-doped Se film was formed as an a-Se layer.

### Embodiment 13

A radiation detecting system was produced in the same manner as the embodiment 12 except that a Se layer doped with 3% As was formed in thickness of 0.2 μm between the a-Se layer and the charge transfer layer.

Whether the peeling off took place was evaluated in the comparative example 4 and the embodiments 12 and 13 in the same manner as the embodiment 4. Result was shown in the following table 4.

TABLE 4

| | | | composition | |
|---|---|---|---|---|
| | | | of charge | |
| | | intermediate | transfer | |
| | a-Se layer | layer | layer | peeling off |
| comparative | Na-doped Se | non | Sb₄₀S₆₀ | X |
| example 4 | | | | |
| embodiment 12 | Na-doped Se | non | Sb₃₃S₆₇ | ◯ |
| embodiment 13 | Na-doped Se | Se layer | Sb₃₃S₆₇ | ◯ |
| | | doped with | | |
| | | 3% As | | |

As can be understood from the description above, since the radiation detecting systems of the present invention include, in their charge-transfer layer, chalcogenide compounds containing therein chalcogenide elements larger than the stoichiometric value by not smaller than 3% of the stoichiometric value in a composition thereof, crystallization of the charge transfer layer can be suppressed, whereby the problem of the image defect which has been believed due to crystallization can be overcome and at the same time, peeling off between the charge-transfer layer and adjacent layers and cracks can be suppressed.

What is claimed is;

1. A radiation detecting system comprising:
a carrier collective electrode layer;
a radiation-sensitive semiconductor layer;
at least one charge transfer layer;
and a voltage applying electrode formed on an insulating substrate,
wherein at least one of the charge transfer layers includes chalcogenide compounds containing therein chalcogenide elements larger than the stoichiometric value by not smaller than 3% of the stoichiometric value in a composition thereof.

2. A radiation detecting system comprising:
at least a carrier collective electrode layer;
a radiation-sensitive semiconductor layer;
at least one charge transfer layer;
and a voltage applying electrode formed on an insulating substrate,
wherein at least one of the charge transfer layers includes chalcogenide compounds containing therein chalcogenide elements larger than the stoichiometric value by not smaller than 3% of the stoichiometric value in the vicinity of at least one of the interfaces of the charge transfer layer in a composition thereof.

3. A radiation detecting system comprising:
at least a carrier collective electrode layer;
a radiation-sensitive semiconductor layer;
at least one charge transfer layer;
and a voltage applying electrode formed on an insulating substrate,
wherein at least one of the charge transfer layers includes chalcogenide compounds containing therein chalcogenide elements which gradually approach the stoichiometric value from the value larger than the stoichiometric value by not smaller than 3% of the stoichiometric value in a composition thereof from the interfaces toward the center.

4. A radiation detecting system as defined in claim 1, wherein the chalcogenide compound is antimony sulfide.

5. A radiation detecting system as defined in claim 1, wherein the radiation-sensitive semiconductor layer is a layer of Na-doped a-Se.

6. A radiation detecting system as defined in claim 5, wherein the carrier collective electrode layer, the radiation-sensitive semiconductor layer, the charge transfer layer, and the voltage applying electrode are formed in this order on the insulating substrate, and the a-Se layer containing at least one of As, Sb and Bi in 0.1 wt % to 10 wt % is provided between the radiation-sensitive semiconductor layer and the charge transfer layer.

7. A radiation detecting system as defined in claim 5, wherein:
the carrier collective electrode layer, the charge transfer layer, the radiation-sensitive semiconductor layer, and the voltage applying electrode are formed in this order on the insulating substrate, and the a-Se layer containing at least one of As, Sb and Bi in 0.1 wt % to 10 wt % is provided between the radiation-sensitive semiconductor layer and the charge transfer layer.
